(19) United States
(12) Patent Application Publication
(10) Pub. No.: US 2025/0044358 A1
(43) Pub. Date: Feb. 6, 2025

(54) IDENTIFYING COMPONENTS TO ACT AS A SOLID-STATE BATTERY USING DIGITAL TWINS

(71) Applicant: INTERNATIONAL BUSINESS MACHINES CORPORATION, ARMONK, NY (US)

(72) Inventors: Sarbajit K. Rakshit, Kolkata (IN); Manikandan Padmanaban, Chennai (IN); Jagabondhu Hazra, Bangalore (IN)

(21) Appl. No.: 18/365,288

(22) Filed: Aug. 4, 2023

(51) Int. Cl. G01R 31/367; B29C 64/393

(52) U.S. Cl. CPC G01R 31/367; B29C 64/393; B33Y 50/02

(57) ABSTRACT

A method, computer system, and a computer program product for battery component identification is provided. The present invention may include receiving data for one or more industrial assets. The present invention may include generating a digital twin for each of the one or more industrial assets. The present invention may include simulating a performance of the digital twin for each of the one or more industrial assets. The present invention may include identifying one or more components of the one or more industrial assets for solid state battery integration based on the simulated performance of the digital twin, wherein the solid state battery integration includes the replacement of the one or more components with a solid state battery or the addition of the solid state battery to the one or more components.

### BACKGROUND

The present invention relates generally to the field of computing, and more particularly to digital twins and battery optimization.

A lithium-ion battery may be composed of a cathode, anode, separator, and/or electrolyte, amongst other components. The lithium-ion battery applied in assets such as, but not limited to, smart phones, power tools, and Electric Vehicles may utilize a liquid electrolyte solution in providing power. On the other hand, a solid state battery may utilize solid electrolytes as opposed to a liquid electrolyte solution. A solid state battery may have a higher energy density than a lithium-ion battery that uses the liquid electrolyte solution while having a lower risk of explosions and/or fires which may alleviate the need for certain safety components. Additionally, a solid state battery may increase energy density per unit of area because a smaller number of batteries may be required in running an asset.

Accordingly, identifying one or more components within these assets which may be replaced with a solid state battery may be advantageous for increasing energy efficiency in these assets without adding additional self-weight.

### SUMMARY

Embodiments of the present invention disclose a method, computer system, and a computer program product for battery component identification. The present invention may include receiving data for one or more industrial assets. The present invention may include generating a digital twin for each of the one or more industrial assets. The present invention may include simulating a performance of the digital twin for each of the one or more industrial assets. The present invention may include identifying one or more components of the one or more industrial assets for solid state battery integration based on the simulated performance of the digital twin, wherein the solid state battery integration includes the replacement of the one or more components with a solid state battery or the addition of the solid state battery to the one or more components.

In another embodiment, the method may include ranking the one or more components which may be replaced with the solid state battery using a machine learning based recommendation system.

In a further embodiment, the method may include receiving a selection of at least one of the one or more components and generating 3D printing instructions based on the at least one of the one or more components selected.

In yet another embodiment, the method may include receiving a selection of at least one of the one or more components from a user within a component optimization interface, monitoring a performance of the at least one of the one or more components within an industrial floor, receiving feedback on at least one of the one or more components from the user within the component optimization interface, and retraining the machine learning based recommendation system based on the performance of and the feedback received for the at least one of the one or more components.

In addition to a method, additional embodiments are directed to a computer system and a computer program product for identifying one or more components of one or more industrial assets which may be replaced with a solid state battery based on digital twin simulations performed.

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

### BRIEF DESCRIPTION OF THE SEVERAL VIEWS OF THE DRAWINGS

These and other objects, features and advantages of the present invention will become apparent from the following detailed description of illustrative embodiments thereof, which is to be read in connection with the accompanying drawings. The various features of the drawings are not to scale as the illustrations are for clarity in facilitating one skilled in the art in understanding the invention in conjunction with the detailed description. In the drawings:

FIG. 1 depicts a block diagram of an exemplary computing environment according to at least one embodiment; and

FIG. 2 is an operational flowchart illustrating a process for battery component identification according to at least one embodiment.

### DETAILED DESCRIPTION

The following described exemplary embodiments provide a system, method and program product for battery component identification. As such, the present embodiment has the capacity to improve the technical field of digital twin technology and battery optimization by identifying one or more components of one or more industrial assets which may be replaced with a solid state battery based on digital twin simulations performed. More specifically, the present invention may include receiving data for one or more industrial assets. The present invention may include generating a digital twin for each of the one or more industrial assets. The present invention may include simulating a performance of the digital twin for each of the one or more industrial assets. The present invention may include identifying one or more components of the one or more industrial assets for solid state battery integration based on the simulated performance of the digital twin, wherein the solid state battery integration includes the replacement of the one or more components with a solid state battery or the addition of the solid state battery to the one or more components.

As described previously, a lithium-ion battery may be composed of a cathode, anode, separator, and/or electrolyte, amongst other components. The lithium-ion battery applied in assets such as, but not limited to, smart phones, power tools, and Electric Vehicles may utilize a liquid electrolyte solution in providing power. On the other hand, a solid state battery may utilize solid electrolytes as opposed to a liquid electrolyte solution. A solid state battery may have a higher energy density than a lithium-ion battery that uses the liquid electrolyte solution while having a lower risk of explosions and/or fires which may alleviate the need for certain safety components. Additionally, a solid state battery may increase energy density per unit of area because a smaller number of batteries may be required in running an asset.

Accordingly, identifying one or more components within these assets which may be replaced with a solid state battery may be advantageous for increasing energy efficiency in these assets without adding additional self-weight.

Therefore, it may be advantageous to, among other things, receive data for one or more industrial assets, generate a digital twin for each of the one or more industrial assets, simulate a performance of the digital twin for each of the one or more industrial assets, and identify one or more components of the one or more industrial assets for solid state battery integration based on the simulated performance of the digital twin, wherein the solid state battery integration includes the replacement of the one or more components with a solid state battery or the addition of the solid state battery to the one or more components.

According to at least one embodiment, the present invention may improve space utilization within one or more industrial assets for more active materials which may increase the battery capacity of the one or more industrial assets by utilizing a solid state battery which may have a higher energy density than a lithium-ion battery which may utilize a liquid electrolyte solution.

According to at least one embodiment, the present invention may improve the stability of one or more industrial assets by identifying space which may be optimized using a solid state battery with a solid state battery.

According to at least one embodiment, the present invention may improve the recommendation of components to be replaced with a solid state battery by monitoring the performance of the at least one of the one or more components selected, receiving feedback from the user on the at least one of the one or more components selected, and retraining a machine learning based recommendation system based on the performance and the feedback received.

According to at least one embodiment, the present invention may improve the capacity of one or more industrial assets of an industrial floor by generating digital twins based on those assets and simulating different stresses on different components and/or parts of those industrial assets based on simulations performed using one or more machine learning models and one or more simulation models to identify components which may be effectively replaced with solid state battery components.

According to at least one embodiment, the present invention may improve the power distribution of the one or more industrial assets by identifying components and/or empty space within the one or more industrial assets which may replaced and/or in which a solid state battery may be added to improve the power distribution. Additionally, the present invention may enable immovable industrial assets to become mobile due to the utilization of a solid state battery source.

According to at least one embodiment, the present invention may improve the performance of one or more industrial assets by identifying components and/or empty space within the one or more industrial assets which may be replaced with a solid state battery to reduce heat generation, limit sound, reduce maintenance requirements, shorten circuits to a power source, provide split power to different components of the one or more industrial assets, amongst other performance improvements.

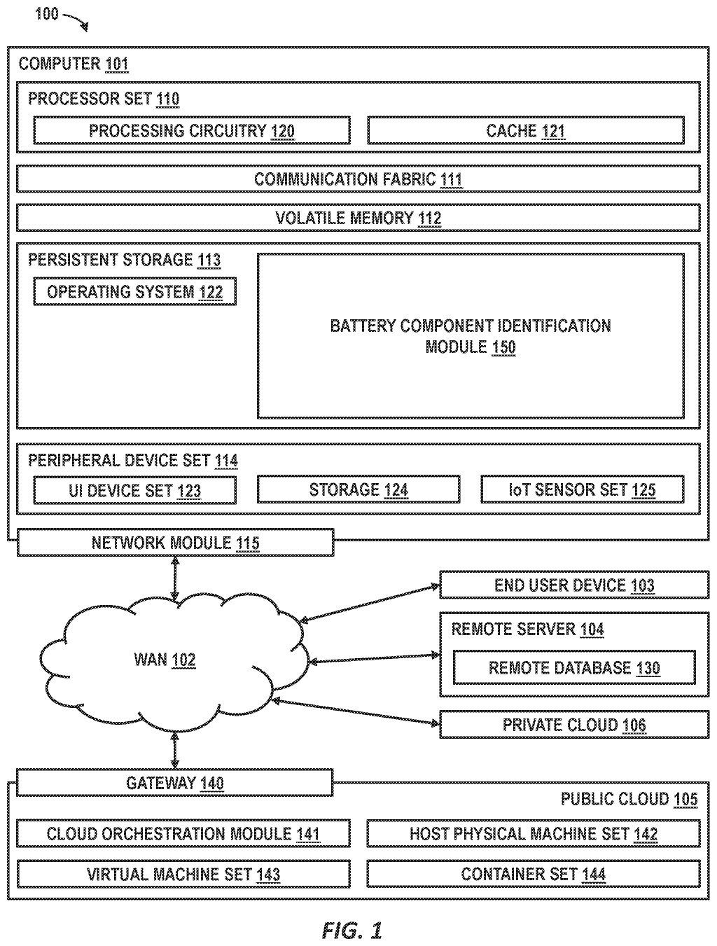

Referring to FIG. 1, Computing environment 100 contains an example of an environment for the execution of at least some of the computer code involved in performing the inventive methods, such as identifying one or more components of one or more industrial assets which may be replaced with a solid state battery based on digital twin simulations performed by the battery component identification module 150. In addition to module 150, computing environment 100 includes, for example, computer 101, wide area network (WAN) 102, end user device (EUD) 103, remote server 104, public cloud 105, and private cloud 106. In this embodiment, computer 101 includes processor set 110 (including processing circuitry 120 and cache 121), communication fabric 111, volatile memory 112, persistent storage 113 (including operating system 122 and module 150, as identified above), peripheral device set 114 (including user interface (UI) device set 123, storage 124, and Internet of Things (IoT) sensor set 125), and network module 115. Remote server 104 includes remote database 130. Public cloud 105 includes gateway 140, cloud orchestration module 141, host physical machine set 142, virtual machine set 143, and container set 144.

Computer 101 may take the form of a desktop computer, laptop computer, tablet computer, smart phone, smart watch or other wearable computer, mainframe computer, quantum computer or any other form of computer or mobile device now known or to be developed in the future that is capable of running a program, accessing a network or querying a database, such as remote database 130. As is well understood in the art of computer technology, and depending upon the technology, performance of a computer-implemented method may be distributed among multiple computers and/or between multiple locations. On the other hand, in this presentation of computing environment 100, detailed discussion is focused on a single computer, specifically computer 101, to keep the presentation as simple as possible. Computer 101 may be located in a cloud, even though it is not shown in a cloud in FIG. 1. On the other hand, computer 101 is not required to be in a cloud except to any extent as may be affirmatively indicated.

Processor Set 110 includes one, or more, computer processors of any type now known or to be developed in the future. Processing circuitry 120 may be distributed over multiple packages, for example, multiple, coordinated integrated circuit chips. Processing circuitry 120 may implement multiple processor threads and/or multiple processor cores. Cache 121 is memory that is located in the processor chip package(s) and is typically used for data or code that should be available for rapid access by the threads or cores running on processor set 110. Cache memories are typically organized into multiple levels depending upon relative proximity to the processing circuitry. Alternatively, some, or all, of the cache for the processor set may be located “off chip.” In some computing environments, processor set 110 may be designed for working with qubits and performing quantum computing.

Computer readable program instructions are typically loaded onto computer 101 to cause a series of operational steps to be performed by processor set 110 of computer 101 and thereby effect a computer-implemented method, such that the instructions thus executed will instantiate the methods specified in flowcharts and/or narrative descriptions of computer-implemented methods included in this document (collectively referred to as “the inventive methods”). These computer readable program instructions are stored in various types of computer readable storage media, such as cache 121 and the other storage media discussed below. The program instructions, and associated data, are accessed by processor set 110 to control and direct performance of the inventive methods. In computing environment 100, at least some of the instructions for performing the inventive methods may be stored in module 150 in persistent storage 113.

Communication fabric 111 is the signal conduction path that allows the various components of computer 101 to communicate with each other. Typically, this fabric is made of switches and electrically conductive paths, such as the switches and electrically conductive paths that make up busses, bridges, physical input/output ports and the like. Other types of signal communication paths may be used, such as fiber optic communication paths and/or wireless communication paths.

Volatile memory 112 is any type of volatile memory now known or to be developed in the future. Examples include dynamic type random access memory (RAM) or static type RAM. Typically, volatile memory 112 is characterized by random access, but this is not required unless affirmatively indicated. In computer 101, the volatile memory 112 is located in a single package and is internal to computer 101, but, alternatively or additionally, the volatile memory may be distributed over multiple packages and/or located externally with respect to computer 101.

Persistent Storage 113 is any form of non-volatile storage for computers that is now known or to be developed in the future. The non-volatility of this storage means that the stored data is maintained regardless of whether power is being supplied to computer 101 and/or directly to persistent storage 113. Persistent storage 113 may be a read only memory (ROM), but typically at least a portion of the persistent storage allows writing of data, deletion of data and re-writing of data. Some familiar forms of persistent storage include magnetic disks and solid state storage devices. Operating system 122 may take several forms, such as various known proprietary operating systems or open source Portable Operating System Interface-type operating systems that employ a kernel. The code included in module 150 typically includes at least some of the computer code involved in performing the inventive methods.

Peripheral device set 114 includes the set of peripheral devices of computer 101. Data communication connections between the peripheral devices and the other components of computer 101 may be implemented in various ways, such as Bluetooth connections, Near-Field Communication (NFC) connections, connections made by cables (such as universal serial bus (USB) type cables), insertion-type connections (for example, secure digital (SD) card), connections made through local area communication networks and even connections made through wide area networks such as the internet. In various embodiments, UI device set 123 may include components such as a display screen, speaker, microphone, wearable devices (such as goggles and smart watches), keyboard, mouse, printer, touchpad, game controllers, and haptic devices. Storage 124 is external storage, such as an external hard drive, or insertable storage, such as an SD card. Storage 124 may be persistent and/or volatile. In some embodiments, storage 124 may take the form of a quantum computing storage device for storing data in the form of qubits. In embodiments where computer 101 is required to have a large amount of storage (for example, where computer 101 locally stores and manages a large database) then this storage may be provided by peripheral storage devices designed for storing very large amounts of data, such as a storage area network (SAN) that is shared by multiple, geographically distributed computers. IoT sensor set 125 is made up of sensors that can be used in Internet of Things applications. For example, one sensor may be a thermometer and another sensor may be a motion detector.

Network module 115 is the collection of computer software, hardware, and firmware that allows computer 101 to communicate with other computers through WAN 102. Network module 115 may include hardware, such as modems or Wi-Fi signal transceivers, software for packetizing and/or de-packetizing data for communication network transmission, and/or web browser software for communicating data over the internet. In some embodiments, network control functions and network forwarding functions of network module 115 are performed on the same physical hardware device. In other embodiments (for example, embodiments that utilize software-defined networking (SDN)), the control functions and the forwarding functions of network module 115 are performed on physically separate devices, such that the control functions manage several different network hardware devices. Computer readable program instructions for performing the inventive methods can typically be downloaded to computer 101 from an external computer or external storage device through a network adapter card or network interface included in network module 115.

WAN 102 is any wide area network (for example, the internet) capable of communicating computer data over non-local distances by any technology for communicating computer data, now known or to be developed in the future. In some embodiments, the WAN 102 may be replaced and/or supplemented by local area networks (LANs) designed to communicate data between devices located in a local area, such as a Wi-Fi network. The WAN and/or LANs typically include computer hardware such as copper transmission cables, optical transmission fibers, wireless transmission, routers, firewalls, switches, gateway computers and edge servers.

End User Device (EUD) 103 is any computer system that is used and controlled by an end user (for example, a customer of an enterprise that operates computer 101), and may take any of the forms discussed above in connection with computer 101. EUD 103 typically receives helpful and useful data from the operations of computer 101. For example, in a hypothetical case where computer 101 is designed to provide a recommendation to an end user, this recommendation would typically be communicated from network module 115 of computer 101 through WAN 102 to EUD 103. In this way, EUD 103 can display, or otherwise present, the recommendation to an end user. In some embodiments, EUD 103 may be a client device, such as thin client, heavy client, mainframe computer, desktop computer and so on.

Remote server 104 is any computer system that serves at least some data and/or functionality to computer 101. Remote server 104 may be controlled and used by the same entity that operates computer 101. Remote server 104 represents the machine(s) that collect and store helpful and useful data for use by other computers, such as computer 101. For example, in a hypothetical case where computer 101 is designed and programmed to provide a recommendation based on historical data, then this historical data may be provided to computer 101 from remote database 130 of remote server 104.

Public cloud 105 is any computer system available for use by multiple entities that provides on-demand availability of computer system resources and/or other computer capabilities, especially data storage (cloud storage) and computing power, without direct active management by the user. Cloud computing typically leverages sharing of resources to achieve coherence and economics of scale. The direct and active management of the computing resources of public cloud 105 is performed by the computer hardware and/or software of cloud orchestration module 141. The computing resources provided by public cloud 105 are typically implemented by virtual computing environments that run on various computers making up the computers of host physical machine set 142, which is the universe of physical computers in and/or available to public cloud 105. The virtual computing environments (VCEs) typically take the form of virtual machines from virtual machine set 143 and/or containers from container set 144. It is understood that these VCEs may be stored as images and may be transferred among and between the various physical machine hosts, either as images or after instantiation of the VCE. Cloud orchestration module 141 manages the transfer and storage of images, deploys new instantiations of VCEs and manages active instantiations of VCE deployments. Gateway 140 is the collection of computer software, hardware, and firmware that allows public cloud 105 to communicate through WAN 102.

Some further explanation of virtualized computing environments (VCEs) will now be provided. VCEs can be stored as “images.” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

Private cloud 106 is similar to public cloud 105, except that the computing resources are only available for use by a single enterprise. While private cloud 106 is depicted as being in communication with WAN 102, in other embodiments a private cloud may be disconnected from the internet entirely and only accessible through a local/private network. A hybrid cloud is a composition of multiple clouds of different types (for example, private, community or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this embodiment, public cloud 105 and private cloud 106 are both part of a larger hybrid cloud.

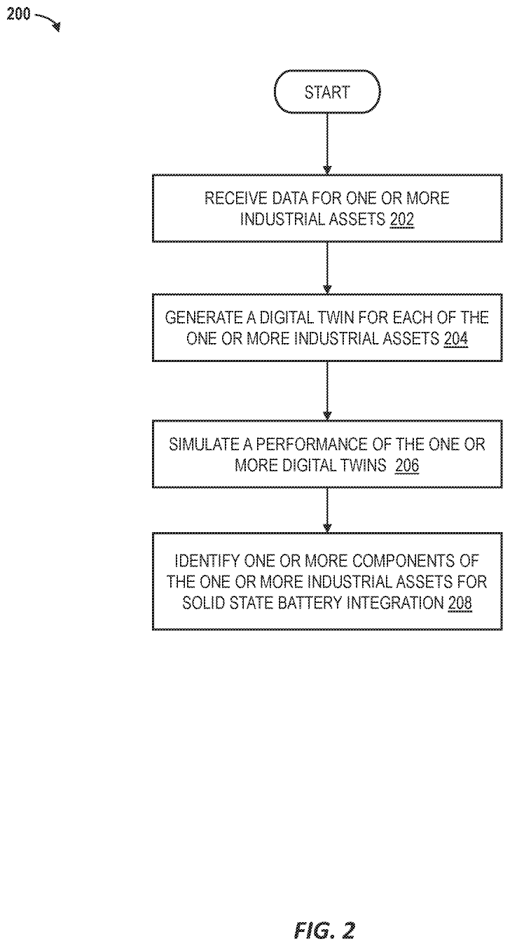

According to the present embodiment, the computer environment 100 may use the battery component identification module 150 to identify one or more components of one or more industrial assets which may be replaced with a solid state battery based on digital twin simulations performed. The battery component identification method is explained in more detail below with respect to FIG. 2.

Referring now to FIG. 2, an operational flowchart illustrating the exemplary battery component identification process 200 used by the battery component identification module 150 according to at least one embodiment is depicted.

At 202, the battery component identification module 150 receives data for one or more industrial assets. The one or more industrial assets may be part of an industrial floor. The battery component identification module 150 may receive and/or access data for an industrial floor and the one or more industrial assets of the industrial floor. The one or more industrial assets may include, but are not limited to including, tools, robots, turning machines, shapers and/or planers, drilling machines, milling machines, grinding machines, power saws, presses, various robotic systems, objects, and/or entities which may be comprised of components that may be replaced with a solid state battery such that the industrial asset may continue to perform the same and/or similar role within the industrial floor and/or physical ecosystem with an increased power efficiency.

The battery component identification module 150 may receive and/or access data for the one or more industrial assets of the industrial floor based on processes performed by the one or more industrial assets. The user may designate particular industrial assets, machines, and/or processes for which the battery component identification module 150 may receive and/or access data in a component optimization interface. The battery component identification module 150 may display the component optimization interface to the user in at least, an internet browser, dedicated software application, and/or as an integration with a third party software application.

The battery component identification module 150 may receive and/or access data for the one or more industrial assets of the industrial floor identified by the user within the component optimization interface from at least, one or more Internet of Things (IoT) devices associated with the one or more industrial assets and/or the industrial floor, images, video, and/or Three-Dimensional (3D) scans of the one or more industrial assets and/or the industrial floor, data provided by the user within the component optimization module, data received directly from the one or more industrial assets, amongst other data which may be received and/or accessed for the one or more industrial assets of the industrial floor. Data provided by the user within the component optimization interface and/or received from the one or more IoT devices and/or images, videos, or 3D scans may include industrial asset details, such as, but not limited to, a brand, model number, bill of materials, product codes, part numbers, design specifications, production processes, engineering information, material composition of parts, functional requirements of the industrial assets, non-functional requirements, maintenance/upkeep records, operating conditions, health of the industrial assets and/or industrial asset components, hours of operation for each industrial asset per day, usage patterns, structural health, Key Performance Indicators (KPI) records, amongst other data.

The battery component identification module 150 may store the data received and/or accessed for the one or more industrial assets and/or the industrial floor in a knowledge corpus (e.g., database 130). As will be explained in more detail below, the battery component identification module 150 may continuously update and/or add data to the knowledge corpus (e.g., database 130) based on additional real time data received. The data stored in the knowledge corpus (e.g., database 130) may be utilized in generating and/or updating the digital twins for each of the one or more industrial assets as well as in monitoring KPIs amongst other metrics utilized in monitoring the one or more assets performing processes on the industrial floor. Although the specification refers specifically to one or more industrial assets and an industrial floor the invention may be applicable more broadly to any assets for which the performance may be improved by optimizing battery capacity.

At 204, the battery component identification module 150 generates a digital twin for each of the one or more industrial assets. The battery component identification module 150 may generate the digital twin for each of the one or more industrial assets of the industrial floor utilized in performing one or more processes identified by the user within the component optimization interface. A digital twin may be a digital representation of at least an object, entity, and/or system that may span the object, entity, and/or system's lifecycle. The digital twin may be updated using real time data, and may utilize, at least, simulation, machine learning, and/or reasoning in aiding informed decision making.

As will be explained in more detail below, the battery component identification module 150 may utilize the digital twin for each of the one or more industrial assets to simulate the capabilities and activities to be performed within the industrial floor based on the data accessed and/or received at step 202. These simulations may be utilized to apply different types of stresses on different parts of the digital twins corresponding to the one or more industrial assets which may utilized to identify which parts of the one or more industrial assets may be candidates for solid state battery replacement.

At 206, the battery component identification module 150 simulates a performance of the one or more digital twins corresponding to the one or more industrial assets in a plurality of conditions. The battery component identification module 150 may simulate the performance of the one or more digital twins in a plurality of conditions based on at least the data stored in the knowledge corpus (e.g., database 130). The plurality of conditions may be utilized to apply different types of stresses on different parts of the digital twins corresponding to different parts of the one or more industrial assets. As will be explained in more detail below, simulations may be utilized to identify one or more components of the one or more industrial assets which may be replaced with a solid state battery and/or for which a solid state batter may be added to the one or more components. The one or more components of the one or more industrial assets may include, but are not limited to including, parts of the industrial asset, empty space within the industrial asset, and/or material compositions of the one or more industrial assets which may be utilized as a solid state battery.

The battery component identification module 150 may utilize one or more machine learning models and/or simulation models in simulating the performance of each of the digital twins under the plurality of conditions. The one or more machine learning models may include, but are not limited to including, Convolutional Neural Networks (CNNs), Artificial Neural Networks (ANNs), Support Vector Machine (SVM), K-Nearest Neighbors (KNN), Naïve Bayes, and/or a hybrid model. The one or more simulation methods may include, but are not limited to including, a Monte Carlo simulation process, agent based simulation model, discrete event simulation model, and/or a system dynamic simulation model, amongst other simulation methods. The battery component identification module 150 may additionally utilize a statistical program such as IBM's SPSS® (SPSS® and all SPSS-based trademarks are trademarks or registered trademarks of International Business Machines Corporation in the United States, and/or in other countries), or Statistical Product and Service Solution, in optimizing the one or more simulation methods.

The battery component identification module 150 may determine the plurality of conditions in which each of the one or more digital twins may be simulated based on the data stored in the knowledge corpus (e.g., database 130) and the one or more processes identified by the user within the component optimization interface. The plurality of conditions may be designed by the battery component identification module 150 to apply different stresses on different body parts and/or components of the digital twins corresponding to the one or more industrial assets utilized in performing the one or more processes identified in order to identify which components of the one or more industrial assets may be candidates for solid state battery replacement while maintaining the performance requirements, usage requirements, KPIs, and other metrics required to perform the one or more processes. The battery component identification module 150 may perform different types of stress simulations, such as, but not limited to, compressive stress simulations, tensile strength simulations, bending stress simulations, share stress simulations, on different portions of the one or more digital twins corresponding to the different portions of the one or more industrial assets. The different types of stress simulations may be performed under a plurality of conditions derived from the data stored in the knowledge corpus (e.g., database 130) to simulate different operational and/or environmental parameters under different payloads and/or types of activities which may enable the battery component identification module to identify the types of solid state battery components which may be candidates for replacement. The battery component identification module 150 may also utilize the simulations in identifying areas in which a solid state battery may be added to an industrial asset without replacing a component.

The battery component identification module 150 may identify components which may be replaced and/or in which a solid state battery may be added based on performance improvements simulated under the plurality of conditions. Performance improvements may include, but are not limited to including, product quality, process efficiency, reduced frequency of maintenance and/or upkeep requirements on the one or more industrial assets, reduced heat generation, reduced sound, shortened circuits to a power source, mobility of the one or more industrial assets, ability to provide multiple sources of power to different components of the one or more industrial assets, reduced movement and/or vibrations in the operation of the industrial asset, amongst other performance improvements.

The battery component identification module 150 may utilize the components of the one or more industrial assets which may be candidates for solid state battery replacement and/or solid state battery addition to generate one or more new digital twins for one or more of the industrial assets. The one or more new digital twins may be generated using the data stored in the knowledge corpus (e.g., database 130) with at least one of the candidate components replaced by a solid state battery and/or an addition of a solid state battery to at least one of the candidate components. The battery component identification module 150 may then utilize the one or more machine learning models and/or simulation models described above to simulate the performance of the one or more new digital twins with the solid state battery component in performing the one or more processes identified by the user within the component optimization interface. The battery component identification module 150 may utilize the simulation data received from each of the simulations in adjusting the solid state battery size, component replaced, amongst other adjustments to optimize the performance metrics of the one or more new digital twins.

At 208, the battery component identification module 150 identifies one or more components of the one or more industrial assets for solid state battery integration based on the simulated performance of the one or more digital twins. Solid state battery integration may include the replacement of the one or more components with a solid state battery or the addition of a solid state battery to the one or more components. The battery component identification module 150 may present the one or more components of the one or more industrial assets which may be replaced with a solid state battery and/or in which a solid state battery may be added to the user within the component optimization interface.

The battery component identification module 150 may rank the one or more components to be replaced with a solid state battery and/or components in which a solid state battery may be added to using a machine learning based recommendation system. The machine learning based recommendation system may utilize at least the performance metrics of the one or more simulations, preferences and/or optimization goals of the user, case of replacement, operating conditions of the industrial floor, usage patterns of the one or more industrial assets in the one or more processes identified by the user, amongst other information in ranking the one or more components to be replaced with the solid state battery. The battery component identification module 150 may display these rankings to the user within the component optimization interface along with details such as projected improvement performance metrics such that the user may evaluate each of the one or more recommendations. The battery component identification module 150 may additionally enable the use to select one or more recommended component replacements and/or component additions from the rankings and enable the user to simulate the performance of the one or more processes over time and provide a comparison of performance metrics between the current state of the industrial floor and the industrial floor with the recommended component replacements and/or component additions. The machine learning based recommendation system may also recommend a reconfiguration of the industrial floor based on the ability of one or more previously immovable industrial assets to be moved to different locations within the industrial floor due to the utilization of a solid state battery source.

In an embodiment, the battery component identification module 150 may generate Three-Dimensional (3D) printing instructions based on the one or more components selected by the user within the component optimization interface to be replaced with the solid state battery power and/or components for which the solid state battery may be added to. The 3D printing instructions may be for the replacement component itself, solid state batteries, other parts required for the replacement, appropriate circuitry for integrating the solid state battery component with the industrial asset, integrating the addition of the solid state battery to the industrial asset, and/or other parts which may be required. The 3D printing instructions may enable the manufacturing processes to be performed in each 3D printing step to be performed in series and/or all the steps to be performed in parallel. The battery component identification module 150 may also generate the 3D printing instructions based on the specifications of a 3D printer to be utilized by the user. The specifications of the 3D printer may include, but are not limited to including, print chamber dimensions, 3D printer make and model, nozzle dimensions, nozzle materials, amongst other specifications. The print chamber dimensions may refer to space available for a 3D printer to print the digital model, wherein the width and length dimensions may be the surface area of a print bed. The print bed may be the part of the 3D printer in which the 3D printed object rests during the printing process. The battery component identification module 150 may retrieve the specifications of the 3D printer from the user within the component optimization interface and/or may retrieve the specifications from publicly available resources, such as the manufacturer's website, for the 3D printer identified by the user within the component optimization interface. Additionally, the battery component identification module may utilize one or more IoT devices associated with the 3D printer in monitoring the printing process and ensuring a quality control process that the printed parts, components, etc. adhere to the structural strength and/or other requirements of the replacement component.

The battery component identification module 150 may provide replacement instructions and/or solid state battery addition instructions to the user for replacing the component of industrial asset with the solid state battery and/or adding the solid state battery to the industrial asset, which may include the relative positions of each part, identification of appropriate circuits which may connect the solid state battery to the industrial asset, assembly instructions, amongst other replacement instructions. Additionally, the battery component identification module 150 may utilize the digital twins in generating images and/or video for the user to assist in component replacement and/or solid state battery addition which may be displayed within the component optimization interface.

The battery component identification module may also monitor the industrial floor based on the real time data described at step 202, the battery component identification module 150 may utilize at least the data received and/or accessed from monitoring the industrial floor and feedback received from the user in retraining the machine learning based recommendation system. The battery component identification module 150 may utilize the real time data in iteratively updating the digital twins for each of the one or more industrial assets of the industrial floor and continuously simulating the one or more updated digital twins to identify additional components which may be replaced with a solid state battery and/or additional components in which a solid state battery may be added. The battery component identification module 150 may also utilize the real time data in monitoring the performance of the one or more components selected by the user within the industrial floor. The battery component identification module 150 may monitor the performance improvements, which may include, but are not limited to including, product quality, process efficiency, reduced frequency of maintenance and/or upkeep requirements on the one or more industrial assets, reduced heat generation, reduced sound, shortened circuits to a power source, mobility of the one or more industrial assets, ability to provide multiple sources of power to different components of the one or more industrial assets, reduced movement and/or vibrations in the operation of the industrial asset, amongst other performance improvements. The battery component identification module 150 may record and store the performance improvements in the knowledge corpus (e.g., database 130) and may utilize data in retraining the machine learning based recommendation system to improve future component rankings. The battery component identification module 150 may also utilize the performance improvement metrics to improve future digital twin simulations.

The battery component identification module 150 may receive feedback from the user within the component optimization interface. The user may be able to select specific industrial assets within a digital representation of the industrial floor and provide feedback which the battery component identification module 150 may analyze using one or more sentiment analysis tools, such as, but not limited to, Natural Language Processing (NLP) techniques, such as those implemented in IBM Watson® (IBM Watson® and all Watson-based trademarks are trademarks or registered trademarks of International Business Machines Corporation in the United States, and/or other countries), IBM Watson® Tone Analyzer, IBM Watson® Natural Language Understanding, IBM Watson® Natural Language Processing, amongst other sentiment analysis tools.

It may be appreciated that FIG. 2 provides only an illustration of one embodiment and do not imply any limitations with regard to how different embodiments may be implemented. Many modifications to the depicted embodiment(s) may be made based on design and implementation requirements.

Various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

A computer program product embodiment (“CPP embodiment” or “CPP”) is a term used in the present disclosure to describe any set of one, or more, storage media (also called “mediums”) collectively included in a set of one, or more, storage devices that collectively include machine readable code corresponding to instructions and/or data for performing computer operations specified in a given CPP claim. A “storage device” is any tangible device that can retain and store instructions for use by a computer processor. Without limitation, the computer readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: diskette, hard disk, random access memory (RAM), read-only memory (ROM), erasable programmable read-only memory (EPROM or Flash memory), static random access memory (SRAM), compact disc read-only memory (CD-ROM), digital versatile disk (DVD), memory stick, floppy disk, mechanically encoded device (such as punch cards or pits/lands formed in a major surface of a disc) or any suitable combination of the foregoing. A computer readable storage medium, as that term is used in the present disclosure, is not to be construed as storage in the form of one or more transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope of the described embodiments. The terminology used herein was chosen to best explain the principles of the embodiments, the practical application or technical improvement over technologies found in the marketplace, or to enable others of ordinary skill in the art to understand the embodiments disclosed herein.

The present disclosure shall not be construed as to violate or encourage the violation of any local, state, federal, or international law with respect to privacy protection.

What is claimed is:

1. A method for battery component identification, the method comprising:
receiving data for one or more industrial assets;
generating a digital twin for each of the one or more industrial assets;
simulating a performance of the digital twin for each of the one or more industrial assets; and
identifying one or more components of the one or more industrial assets for solid state battery integration based on the simulated performance of the digital twin, wherein the solid state battery integration includes the replacement of the one or more components with a solid state battery or the addition of the solid state battery to the one or more components.

2. The method of claim 1, wherein the performance of the digital twin is simulated under a plurality of conditions based on data stored in a knowledge corpus and one or more processes identified by a user.

3. The method of claim 1, further comprising:
ranking the one or more components which may be replaced with the solid state battery using a machine learning based recommendation system.

4. The method of claim 3, wherein the ranking of the one or more components is displayed to a user within a component optimization interface.

5. The method of claim 3, further comprising:
receiving a selection of at least one of the one or more components; and
generating 3D printing instructions based on the at least one of the one or more components selected.

6. The method of claim 3, further comprising:
receiving a selection of at least one of the one or more components from a user within a component optimization interface;
monitoring a performance of the at least one of the one or more components within an industrial floor;
receiving feedback on the at least one of the one or more components from the user within the component optimization interface; and
retraining the machine learning based recommendation system based on the performance of and the feedback received for the at least one of the one or more components.

7. The method of claim 1, wherein the performance of the digital twin is simulated using one or more machine learning models and one or more simulation models.

8. A computer system for battery component identification, comprising:
one or more processors, one or more computer-readable memories, and one or more computer-readable storage media;
program instructions, stored on at least one of the one or more computer-readable storage media for execution by at least one of the one or more processors via at least one of the one or more memories, to receive data for one or more industrial assets;
program instructions, stored on at least one of the one or more computer-readable storage media for execution by at least one of the one or more processors via at least one of the one or more memories, to generate a digital twin for each of the one or more industrial assets;
program instructions, stored on at least one of the one or more computer-readable storage media for execution by at least one of the one or more processors via at least one of the one or more memories, to simulate a performance of the digital twin for each of the one or more industrial assets; and
program instructions, stored on at least one of the one or more computer-readable storage media for execution by at least one of the one or more processors via at least one of the one or more memories, to identify one or more components of the one or more industrial assets for solid state battery integration based on the simulated performance of the digital twin, wherein the solid state battery integration includes the replacement of the one or more components with a solid state battery or the addition of the solid state battery to the one or more components.

9. The computer system of claim 8, wherein the performance of the digital twin is simulated under a plurality of conditions based on data stored in a knowledge corpus and one or more processes identified by a user.

10. The computer system of claim 8, further comprising:
program instructions, stored on at least one of the one or more computer-readable storage media for execution by at least one of the one or more processors via at least one of the one or more memories, to rank the one or more components which may be replaced with the solid state battery using a machine learning based recommendation system.

11. The computer system of claim 10, wherein the ranking of the one or more components is displayed to a user within a component optimization interface.

12. The computer system of claim 10, further comprising:
program instructions, stored on at least one of the one or more computer-readable storage media for execution by at least one of the one or more processors via at least one of the one or more memories, to receive a selection of at least one of the one or more components; and
program instructions, stored on at least one of the one or more computer-readable storage media for execution by at least one of the one or more processors via at least one of the one or more memories, to generate 3D printing instructions based on the at least one of the one or more components selected.

13. The computer system of claim 10, further comprising:
program instructions, stored on at least one of the one or more computer-readable storage media for execution by at least one of the one or more processors via at least one of the one or more memories, to receive a selection of at least one of the one or more components from a user within a component optimization interface;
program instructions, stored on at least one of the one or more computer-readable storage media for execution by at least one of the one or more processors via at least one of the one or more memories, to monitor a performance of the at least one of the one or more components within an industrial floor;
program instructions, stored on at least one of the one or more computer-readable storage media for execution by at least one of the one or more processors via at least one of the one or more memories, to receive feedback on the at least one of the one or more components from the user within the component optimization interface; and
program instructions, stored on at least one of the one or more computer-readable storage media for execution by at least one of the one or more processors via at least one of the one or more memories, to retrain the machine learning based recommendation system based on the performance of and the feedback received for the at least one of the one or more components.

14. The computer system of claim 8, wherein the performance of the digital twin is simulated using one or more machine learning models and one or more simulation models.

15. A computer program product for battery component identification, comprising:
one or more computer-readable storage media;
program instructions, stored on at least one of the one or more computer-readable storage media, to receive data for one or more industrial assets;
program instructions, stored on at least one of the one or more computer-readable storage media, to generate a digital twin for each of the one or more industrial assets;
program instructions, stored on at least one of the one or more computer-readable storage media, to simulate a performance of the digital twin for each of the one or more industrial assets; and
program instructions, stored on at least one of the one or more computer-readable storage media, to identify one or more components of the one or more industrial assets for solid state battery integration based on the simulated performance of the digital twin, wherein the solid state battery integration includes the replacement of the one or more components with a solid state battery or the addition of the solid state battery to the one or more components.

16. The computer program product of claim 15, wherein the performance of the digital twin is simulated under a plurality of conditions based on data stored in a knowledge corpus and one or more processes identified by a user.

17. The computer program product of claim 15, further comprising:
program instructions, stored on at least one of the one or more computer-readable storage media, to rank the one or more components which may be replaced with the solid state battery using a machine learning based recommendation system.

18. The computer program product of claim 17, wherein the ranking of the one or more components is displayed to a user within a component optimization interface.

19. The computer program product of claim 17, further comprising:
program instructions, stored on at least one of the one or more computer-readable storage media, to receive a selection of at least one of the one or more components; and
program instructions, stored on at least one of the one or more computer-readable storage media, to generate 3D printing instructions based on the at least one of the one or more components selected.

20. The computer program product of claim 17, further comprising:
program instructions, stored on at least one of the one or more computer-readable storage media, to receive a selection of at least one of the one or more components from a user within a component optimization interface;
program instructions, stored on at least one of the one or more computer-readable storage media, to monitor a performance of the at least one of the one or more components within an industrial floor;
program instructions, stored on at least one of the one or more computer-readable storage media, to receive feedback on the at least one of the one or more components from the user within the component optimization interface; and
program instructions, stored on at least one of the one or more computer-readable storage media, to retrain the machine learning based recommendation system based on the performance of and the feedback received for the at least one of the one or more components.
